(19) United States
(12) Patent Application Publication
(10) Pub. No.: US 2003/0044727 A1
(43) Pub. Date: Mar. 6, 2003

(54) Method for manufacturing transparent soft mold for forming barrier ribs of PDP and method for forming barrier ribs using the same

(76) Inventors: Lee Soon Park, Daegu (KR); Seung Won Jeong, Daegu (KR); Kyoung Seok Shin, Gyeonggi-Do (KR); Bok Sik Song, Seoul (KR); Keon Hwan Kim, Seoul (KR); Kwang Ho Lee, Seoul (KR); Jeong Woong Choi, Gyeonggi-Do (KR); Jong Woo Park, Daegu (KR); Sin Hye Paek, Busan (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/222,384

(22) Filed: Aug. 16, 2002

(30) Foreign Application Priority Data
Aug. 24, 2001 (KR) 2001-51452
Aug. 24, 2001 (KR) 2001-51454
Aug. 24, 2001 (KR) 2001-51456

(51) Int. Cl. G03F 7/00

(52) U.S. Cl. 430/320; 430/322; 430/324; 430/330

(57) ABSTRACT

Provided is a method for forming barrier ribs of a plasma display panel (PDP), in which the rear substrate is protected from camber and damage occurring in the pressing process, and the mold can be separated easily by manufacturing a soft mold using elastic silicon rubber and forming uniform barrier ribs in a press method using the soft mold. In addition, a method for manufacturing a transparent soft mold is suggested, and uniform barrier ribs are formed by pressing a photosensitive barrier rib paste with the transparent soft mold, exposing them to a particular light source to reduce contact surface between the mold and the paste and thus make the mold separated easily.

### FIELD OF THE INVENTION

The present invention relates to a plasma display panel (PDP) manufacturing technology, and more particularly, to a method for manufacturing a transparent soft mold for forming barrier ribs of the PDP and a method for forming the barrier ribs using the same.

### DESCRIPTION OF RELATED ART

A plasma display panel (PDP) is a device for displaying a picture using plasma generated by discharge gases. It is known as a gas discharge display device. In the PDP, discharge gases, such as Ne and Xe, are supplied into a space between the upper and lower plates, and an ultraviolet ray generated from the discharge gases excites red (R), green (G) and blue (B) fluorescents and produce visible light.

The PDP is divided into two types: a direct current (DC) type and an alternating current (AC) type. In a DC type PDP, electrodes used for applying voltage to form plasma is exposed directly to the plasma, and thus, a conduction current flows directly between the electrodes. The DC type PDP has advantage that the structure is relatively simple. On the other hand, the DC type PDP has a disadvantage that the external resistor has to be placed to limit the current, because the electrodes are exposed to the discharge gases. In the AC type PDP, the electrodes are covered with the dielectric substances so that the electrodes are not exposed directly to the discharge gas and flow of displacement current. The AC type PDP has longer life span, compared with the DC type PDP, because the electrodes of the AC type PDP are covered with the dielectric substances to limit the current and can be protected from an ion impact. The AC type PDP can be classified into an opposite discharge type and a surface discharge type. The opposite discharge type has the disadvantage that the life span is shortened by the degradation of the fluorescent substances owing to the ion impact. In the surface discharge type, on the other hand, the discharge is collected in a panel opposite to the fluorescent substances in order to minimize the degradation of the fluorescent substances, therefore, the surface discharge type is adopted to most of the PDP manufacturing processes.

Since the PDP can easily embody a thin and large size screen among various flat displays, its applicable fields expands from bulletin boards of a stock exchange market and displays for video conference, to recently developed large-size flat panel TV.

Referring to FIG. 1, which is a cross-sectional view illustrating a surface-discharged AC type of a PDP, the surface-discharged AC type PDP comprises a rear plate and a front plate. The rear plate is formed of a rear glass substrate 10, an address electrode 11, a white dielectric 12, and barrier ribs 13. The front plate is formed of a front glass substrate 14, transparent electrode 15, bus electrodes 16, transparent dielectric layer 17, a dielectric protection layer 18, black stripes (not shown). The fluorescents (R, G, B) 19 for embodying colors in the PDP are placed on the front plate in case of a transparent type. In case of a reflective type, the fluorescents are placed between the barrier ribs 13 of the rear plate, as illustrated in the drawing.

It is hard to form the barrier ribs, because the barrier ribs are formed in three-dimensional with a linewidth around 50˜80 μm. Methods for forming barrier ribs of a PDP include screen printing, sandblasting, photolithography, press method, and rolling method.

In the screen printing method, the process or printing and drying is repeated several times utilizing a screen mask to obtain a desired pattern. Since this process should be performed repeatedly until the desired height are obtained, there are problems, such as slanting barrier ribs, unstable discharge resulting from the high deviation of the barrier ribs height, dropping uniformity in the formation of fluorescent substances, screen mask mesh marks. Accordingly, throughput is decreased due to the low reproducibility of the screen printing method.

In the sandblasting method, barrier ribs are formed through the process of coating a barrier rib paste to a thickness of 300˜400 μm and drying it, laminating a sanding-resistant dry film resist (DFR) to it, performing patterning through light exposure and development, and polishing the barrier rib paste with fine abrasive granule by using the pattern as a mask. The sandblasting method is advantageous in that it can form fine barrier ribs, compared to the press method, but it has disadvantages that the process is complicated and has high material loss. In addition, it is difficult to separate powder mixture generated in the sandblasting, and since the powder mixture is a polluting material, the sandblasting method is not environment-friendly.

In the photolithographic method to form the barrier ribs, a photosensitive barrier rib paste is coated, dried, and exposed to light through a photo mask. Then, the paste of the unexposed areas is dissolved selectively in development solution and removed. The photolithographic method is advantageous because the dimensions of barrier ribs can be controlled precisely. However, the method has disadvantages that the paste loss is high and barrier ribs over 100 μm can hardly be formed, because the lower portion of the photosensitive barrier rib paste cannot be exposed to light.

FIGS. 2A through 2C are cross-sectional views showing the conventional process for forming barrier ribs using a press method. To form barrier ribs in the conventional press method, first, green tape 21, including a polymer barrier rib composite layer, is adhered to the glass substrate 20, and a metal mold 22 engraved with a barrier rib pattern is aligned over the green tape 21, as shown in FIG. 2A. Then, as depicted in FIG. 2B, the metal mold 22 is pressed to the green tape 21 on the glass substrate 20. Subsequently, as shown in FIG. 2C, the metal mold 22 is separated in the vertical direction and thereby the barrier ribs 21a is formed.

The conventional press method, which is described above, is advantageous in that the process is very simple and the material is hardly wasted, but it has disadvantages that the height of the barrier ribs 21a is not uniform, and the glass substrate 20 may be damaged by the pressure applied to the metal mold 22. In addition, it is hard to detach the green tape 21 from the metal mold 22 after the pressing process.

Meanwhile, a rolling mold method is suggested to reduce damage of the glass substrate caused by the high pressure in the pressing processing, which is the shortcoming of the press method. In the rolling mold method, a metal cylinder, i.e., rolling mold, which is engraved with barrier rib pattern in the shape of stripe on the outer circumferential surface, is rolled and pressed on the barrier rib paste coated on a substrate. Since the rolling mold is rolled in the horizontal direction to form the barrier ribs, less pressure is applied to the glass substrate, compared to the conventional press method. Accordingly, there are advantages that the damage on the glass substrate is prevented, and the troublesome separation process is relieved. However, due to the difficulty in tinkering with metal, it is hard to make precise mold. Naturally, the cost for making mold is expensive, and since the paste adheres to the mold during the rolling process, it is difficult to obtain a fine barrier rib pattern with uniform heights in the repeated process.

### SUMMARY OF THE INVENTION

It is, therefore, an object of the present invention to provide a method for forming barrier ribs of a plasma display panel (PDP) and a method for manufacturing a mold therefore, which can form fine barrier ribs with uniform heights even in the repeated process.

It is another object of the present invention to provide a method for forming barrier ribs of a PDP, which can form barrier ribs of a uniform height, prevents camber or damage of a substrate, and separates the mold easily after a pressing process is completed.

In accordance with an aspect of the present invention, there is provided a method for manufacturing a transparent soft mold for forming barrier ribs of a plasma display panel, comprising the steps of: coating a photoresist on a substrate, the surface of the substrate coated with an adhesive; forming a basic mold frame which is made of the photoresist and defines a barrier rib pattern; pouring a liquid-phase transparent rubber material to the basic mold frame; hardening the liquid-phase transparent rubber material; and obtaining a transparent soft mold by separating the hardened rubber material from the basic mold frame.

In accordance with another aspect of the present invention, there is provided a method for forming barrier ribs of a plasma display panel, comprising the steps of: preparing a mold which is made of a transparent rubber material and engraved with a barrier rib pattern; forming a material layer for barrier ribs on a substrate; aligning the mold on the material layer for barrier ribs; pressing the material layer for barrier ribs with the mold; inducing a photopolymerization reaction in the material layer for barrier ribs by exposing the material layer for barrier ribs to light; separating the mold from the material layer for barrier ribs; and forming barrier ribs by performing plasticity process on the material layer for barrier ribs.

This invention manufactures a mold using an elastic silicon rubber to form a uniform barrier rib pattern, and make the separation of mold easy as well as prevent cambering or damage of the rear substrate, and forms barrier ribs in a press method using the silicon rubber mold.

The present invention manufactures a transparent mold, presses the mold on a photosensitive barrier rib paste, exposes the paste to a particular light source and reduce the adhesiveness between the mold and the barrier ribs to make the separation easy, and thus forms uniform, fine barrier ribs.

The present invention manufactures a soft mold by using an elastic rubber material, such as silicon rubber or urethane rubber, and attaching the soft mold on the outer circumferential surface of a metal cylinder, and then performs a rolling mold method which has little surface tension and fraction force, to make the separation easy and form uniform, fine barrier ribs.

### BRIEF DESCRIPTION OF THE DRAWING(S)

The above and other objects and features of the present invention will become apparent from the following description of the preferred embodiments given in conjunction with the accompanying drawings, in which:

FIG. 1 is a cross-sectional view illustrating a surface-discharged AC type plasma display panel (PDP);

FIGS. 2A through 2C are cross-sectional views showing the conventional process for forming barrier ribs using a press method;

FIGS. 3A through 3C are cross-sectional views showing the process for forming barrier ribs of a PDP using a soft mold in accordance with a first embodiment of the present invention;

FIGS. 4A through 4C are cross-sectional views depicting the process for forming barrier ribs of a PDP using a transparent mold in accordance with a second embodiment of the present invention;

FIG. 5 represents diagrams showing a method of manufacturing a soft rolling mold used for forming barrier ribs of a PDP in accordance with a third embodiment of the present invention; and

FIGS. 6A through 6C are perspective diagrams illustrating a method for forming barrier ribs of a PDP using the soft rolling mold in accordance with the third embodiment of the present invention.

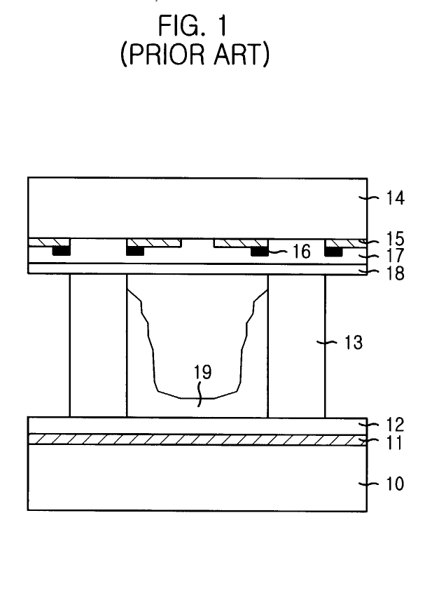

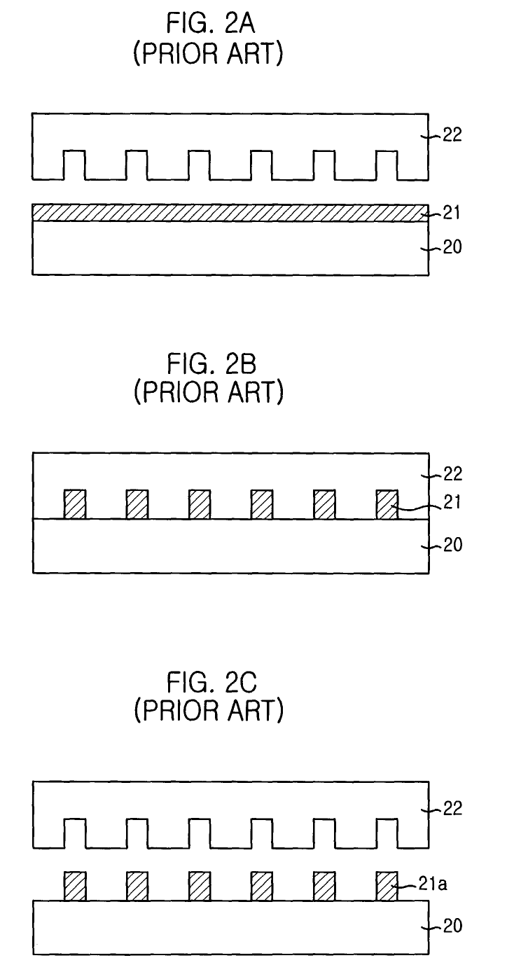

### DETAILED DESCRIPTION OF THE INVENTION

Other objects and aspects of the invention will become apparent from the following description of the embodiments with reference to the accompanying drawings.

A first embodiment of the present invention, in which barrier ribs of a plasma display panel (PDP) is formed by making a silicon mold and using non-photosensitive barrier rib paste, will be described hereinafter. First, a silicon coupling agent, e.g., Z-6040 of Dow Corning Company, is coated to a thickness of 0.1˜0.2 μm. Then, a negative photoresist process is performed to form a thick layer over 300 μm, that is, SU8 of Microchem Company is coated and dried at 90° C. for 20 minutes.

Subsequently, light exposure is performed through a photomask, on which a barrier rib pattern is drawn, and development is performed to form a basic mold. Here, the wavelength of the light source is 360˜420 nm and the light energy of 600˜1200 mJ/cm² is supplied.

Then, liquid silicon rubber material (for example, SH9555 of Dow Corning Company, in which silicon solution and hardening agent are mixed in the ratio of 5˜15:1) is poured to the basic mold frame, and after air bubbles are removed, the mold frame is hardened in the oven at about 50° C. for around 30 minutes. The hardened silicon rubber is separated from the basic mold frame, and thus the soft mold is obtained.

As described above, in this invention, a mold for forming barrier ribs of a PDP is manufactured using silicon rubber. In the present invention, silicon coupling agent is used as an adhesive agent, when the basic mold frame is manufactured using a photoresist. Silicon coupling agent secures stable mold manufacture due to excellent adhesiveness between the surface of the glass substrate and the photoresist. Also, in case of manufacturing a mold through the above procedures, various cell structure, i.e., the structure of barrier ribs, can be embodied by altering the design of photomask.

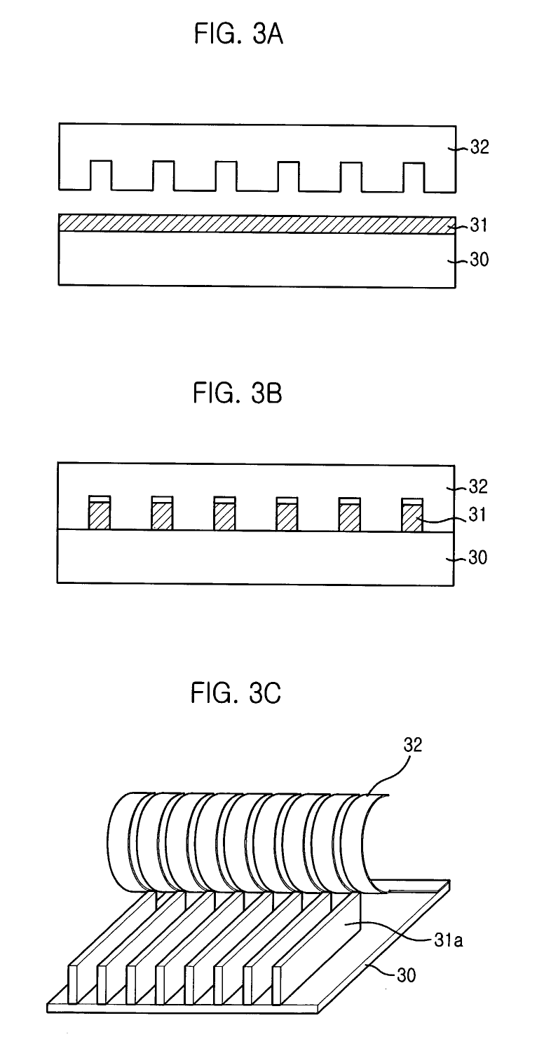

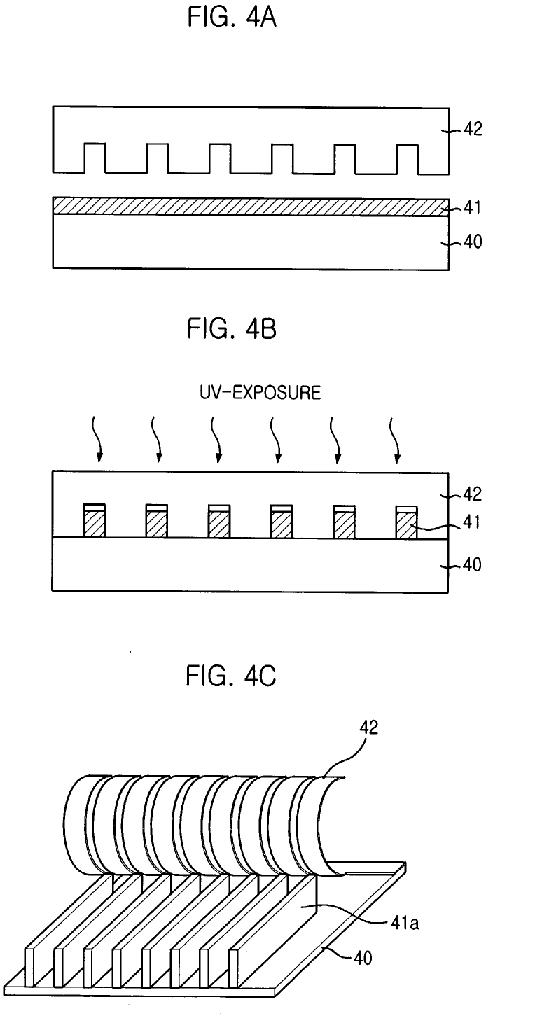

FIGS. 3A through 3C are cross-sectional views showing the process for forming barrier ribs of a PDP using a soft mold in accordance with a first embodiment of the present invention. Referring to FIG. 3A, the barrier rib paste 31 is coated to a thickness of 200˜300 μm on the rear glass substrate 30, and dried in the drying oven to remove 70˜80% of the solvent in the barrier rib paste 31.

Referring to FIG. 3B, the soft mold 32 is aligned on the rear glass substrate 30, and pressed at 30˜80° C. Here, it is good to design the intaglio pattern of the soft mold 32 150˜200% higher than the prearranged height of barrier ribs, so that the barrier rib paste 31 is pressed to the soft mold 32 with a predetermined space in between when an appropriate pressure is applied to the soft mold 32. This way, the soft mold 32 can be separated easily.

Subsequently, as illustrated in FIG. 3C, the soft mold 32 is separated gradually as if it were rolled up from the border to the center, so that the contact surface between the pressed barrier rib paste 31 and the soft mold 32 is reduced. Then, a plasticity process is performed at the temperature of 550˜580° C., thus removing organic materials in the barrier rib paste 31 and maintaining inorganic material to form barrier ribs 31a with a height of 110˜130 μm.

The above method has an advantage that the process is simple just as the conventional press method, and since a soft mold is used instead of a metal mold, the glass substrate is hardly destroyed during the pressing. In addition, the elasticity of the soft mold makes it easy to separate the mold. The height of the barrier ribs formed according to the embodiment of the present invention shows a deviation of less than 1% from the average height, while that of the barrier ribs formed in the conventional press method has a deviation of 10% from the average height.

Hereinafter, as a second embodiment of the present invention, in which a transparent soft mold using silicon rubber is manufactured and the barrier ribs are formed by utilizing the transparent soft mold and a photosensitive barrier rib paste, will be described.

First, the manufacturing of the transparent mold using silicon rubber is similar to the first embodiment. However, in this embodiment, it is desirable to pour a two-component type transparent silicon rubber material into the basic mold frame. The two-component type transparent silicon rubber material is hardened at room temperature after removing air bubbles it is desirable to make the silicon rubber mold have an optical transmittance of over 80% at a certain light source, for example, the wavelength of 365 nm. When a mold is manufactured in this method, various structures of barrier ribs can be embodied easily just by changing the design of a photomask.

Also, in the second embodiment, the photopolymerizing photosensitive barrier rib paste is prepared by incorporating inorganic barrier rib powder, binder polymer, multifunctional monomer or oligomer, UV photoinitiator, release agent, and solvent. By performing a polymerization induced phase separation (PIPS) method, which utilizes the effect of phase separation by photopolymerization, the release agent and residual solvent are separated on the surface of the barrier rib paste. The photopolymerization makes the polymer shrink and thus the mold can be separated easily. Additional agents, such as dispersing agent, photo-sensitizer, antifoaming agent, leveling agent, antioxidant, and polymerization inhibitor may be added to the photopolymerizing photosensitive barrier rib paste.

Meanwhile, the second embodiment of the present invention uses a photopolymerizing photosensitive barrier rib paste composition so that the mold can be separated from the pressed barrier rib paste easily. Particularly, this embodiment suggests a photopolymerizing photosensitive barrier rib paste which has a composition of 4˜8 wt % binder polymer, 10˜13 wt % multifunctional monomer or oligomer, 70˜72 wt % inorganic barrier rib powder, 1˜2 wt % photoinitiator, 0.5˜1.0 wt % release agent, and trace amount of residual solvent. In addition, 1˜2 wt % additives, such as dispersing agent, photosensitizer, antifoaming agent, leveling agent, antioxidant, and polymerization inhibitor may be added to the photopolymerizing photosensitive barrier rib paste.

In the above photosensitive barrier rib paste, the binder polymer serves the roles of combining the inorganic barrier rib powder, and controlling its viscosity. Instead, multifunctional monomer or oligomer and other polymer with fine miscibility may be used. Preferably, such binder polymer as cellulose family and acrylate family may be used. Such cellulose derivatives as hydroxyethyl cellulose, hydroxypropyl celluose, and hydroxyethylhydroxypropyl cellulose may represent the cellulose family, and one selected from the group of the cellulose derivatives may be used as binder polymer. These cellulose derivatives makes it possible to perform plasticity process at a temperature as low as around 480° C. in the final plasticity step of the barrier rib forming process.

As for the multifunctional monomer, one selected from the acrylate family, such as ethyleneglycol diacrylate, diethyleneglycol diacrylate, trimethylol triacrylate, may be used. For the multifunctional oligomer, there are Ebecryl 600, 605, 616, 639, and 1608 commercially provided by UCB Company as epoxy acrylate oligomer; Ebecryl 264, 265, 284, and 8804 as aliphatic urethane acrylate oligomer; Ebecryl 220, 4827, and 4849 as aromatic urethane acrylate oligomer; and Ebecryl 80 and 150 as polyester acrylate oligomer.

For the inorganic barrier rib powder, a mixture of frit glass powder and a metal oxide selected from the group of Cr₂O₃, CuO, Fe₂O₃, K₂O, MnO, PbO, SiO₂, ZrO₂, B₂O₃, TiO₂, and Al₂O₃ is used.

For the photoinitiator, any photoinitiator with excellent optical reaction in the UV wavelength of 350˜430 nm can be used. For example, 2,2-demethoxy-2-phenyl acetophenone (DMPA) alone, or a mixed photoinitiator, in which two or more photoinitiators are mixed, may be used. When a mixed photoinitiator is used, an excellent barrier rib pattern can be obtained, because crosslinking can be obtained in several wavelength zone. Accordingly, it is possible to use 1-hydroxy-cyclohexyl-phenylketone, p-phenylbenzophenone, benzyldimethylketal, 2,4-dimethylthioxanthone, 2,4-diethylthioxanthone, benzoin ethyl ether, benzoin isobutyl ether, 4,4′-diethylaminobenzophenone, or p-dimethyl amino benzoic acid ethylester singly, or by mixing two or more of them.

The release agent is used to make the transparent mold separated easily from the photosensitive barrier rib paste after the pressing process. Such release agents as Zn stearate, dimethyl silicone resin, those of an organic family or a silicon family may be used.

To enhance the photosensitivity of the photosensitive barrier rib paste, various additional agents may be used, such as, photo-sensitizer, e.g., benzophenone or isopropyl thioxthanthone; polymerization inhibitor, e.g., hydroquinone; dispersing agent, e.g., Alcosperse 602-N of an acrylic family; antifoaming agent, e.g., BYK 307 of a silicon family; leveling agent, e.g., BYK 320; and an antioxidant, e.g., Iganox 1010 of Cyba geigy company.

As solvent for the photosensitive barrier rib paste, one of butyl carbitol and butyl carbitol acetate, 3-methoxy-3-methyl butanol, terpineol, dimethyl formamide, or dimethyl acetamide, which has a boiling point of over 100° C. may be used singly, or a mixture of two or more of them may be used.

The release agent and residual solvent are separated on the surface of the pressed composition by irradiating UV light to the above-described photosensitive barrier rib paste composition, which is a polymerization induced phase separation using the effect of phase separation by photopolymerization. Since the polymer shrink due to the photopolymerization and thus the contact surface of the barrier rib paste becomes reduced, the mold can be separated easily from the barrier rib paste.

Meanwhile, it is preferable that the photopolymerizing photosensitive barrier rib paste composition has a viscosity of 80,000˜200,000 cps. If its viscosity becomes lower than 80,000, the barrier rib paste is not printed very well in the coating step, and in the pressing step, the barrier rib paste may be deformed due to its Theological property, after the barrier rib structure is formed by the transparent soft mold. Likewise, when the viscosity exceeds 200,000 cps, the barrier rib paste is not printed well, either, because the elastic transparent mold can hardly form the barrier ribs.

FIGS. 4A through 4C depicts the process for forming barrier ribs of a PDP using a transparent mold in accordance with a second embodiment of the present invention. First, referring to FIG. 4A, the photopolymerizing photosensitive barrier rib paste 31 is coated on the rear glass substrate 40 to a thickness of 200˜300 μm. The photopolymerizing photosensitive barrier rib paste used here is the same as the one used in the above.

Subsequently, referring to FIG. 4B, the transparent mold 42 is aligned on the substrate and pressed. The mold and the photopolymerizing photosensitive barrier rib paste 41 still attached to each other is exposed to UV light. Here, the intensity of the UV light is 10 mW/cm² and the exposure to the UV light is performed for 30˜50 seconds. If the total light energy is in the range of 300˜500 mJ/cm², the one-time light exposure is sufficient for the photopolymerizing photosensitive barrier rib paste 41. It is good to design the intaglio pattern of the transparent mold 42 higher than the prearranged height of the barrier ribs so that the barrier rib paste 41 and the transparent mold 42 are pressed with a regular space in between, because this makes the separation of the transparent mold 42 easy.

Referring to FIG. 4C, the transparent mold 42 is separated, and a plasticity process is performed at 550˜580° C. to burn out all organic materials in the photopolymerizing photosensitive barrier rib paste 41. Then inorganic barrier rib material is maintained, and barrier ribs with the height of 110˜130 μm can be obtained.

As described above, the present invention uses a photopolymerizing photosensitive barrier rib paste as a material for barrier ribs, and barrier ribs are formed by using a transparent mold and performing the pressing process. Then, UV light exposure is performed on the barrier rib paste with the transparent mold still attached thereto. As a result, the polymer in the barrier rib paste shrinks due to the photopolymerization, generating a gap between the mold and the barrier rib paste. By the PIPS process, release agent and residual solvent move to the surface of the composition and this make the mold separated easy. As a transparent mold is used here, it is easy to align it over the electrodes.

The above-described method has advantages that the process is simple just as the conventional press method, and because the transparent mold is made of elastic silicon rubber, the glass plate is hardly damaged. Following is a result of an experiment that shows difference between the second embodiment of the present invention and the prior art.

Experimental Result 1

4.0 g (4.3%) of Ethyl cellulose (EC) with molecular weight of 77,000 g/mole is dissolved in a mixed solvent in which butyl cabitol (BCA) and butyl cabitol acetate (BC) are mixed in the ratio of 7:3, and then 0.5 g (0.5%) of dispersing agent, 0.1 g (0.1%) of antifoaming agent, 0.6 g (0.6%) of silicon release agent, and 64.6 g (70.0%) of frit glass powder are added to it and get mixed. Then, a barrier rib paste composition is formulated by dispersing the mixture uniformly with a kneader, and the paste is coated on a glass substrate, in which dielectrics and electrodes are already formed, with doctor blade applicator to a thickness of 400 μm. Subsequently, the substrate is dried in a IR oven at 110° C. for 20 minutes, dropping the amount of residual solvent less than 5%. After the paste is pressed with a metal mold, the mold is lifted up directly to be separated (Prior art). Here, it is found out that some barrier ribs become out of shape or destroyed. The height of the barrier ribs has a deviation of about 20% from the average height.

Experimental Result 2

A photopolymerizing photosensitive barrier rib paste is formulated by mixing 4.2 wt % hydroxypropyl cellulose (HPC) as binder polymer, 16.7 wt % 3-methoxy-3-methyl butanol (3MMB) as solvent, 4.2 wt % pentaerythritol triacrylate (PETA) as multifunctional monomer, 4.2 wt % hydroxyethyle acrylate as multifunctional monomer, 0.7 wt % HSP-188 as photoinitiator, and 7 wt % barrier rib powder as inorganic corpuscle. The paste is coated on the entire surface of the rear to a thickness of 400 μm, and dried until the amount of residual solvent becomes about 20%. Subsequently, a transparent mold is aligned, pressed, and exposed to UV light with an intensity of 10 mW/cm2 for 50 seconds. Then the transparent soft mold is separated as if it were rolled up (Present invention). Here, the formed barrier ribs are the same as the ones designed in the transparent mold, and their height has a deviation of less than 1% from the average height. After a plasticity process is performed at 550° C., barrier ribs with 120 μm height are obtained.

Hereinafter, a third embodiment, which involves a method for manufacturing a soft rolling mold and a method for forming barrier ribs of a PDP using the soft rolling mold, is described.

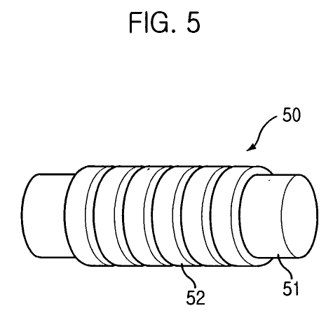

FIG. 5 shows a method of manufacturing a soft rolling mold used for forming barrier ribs of a PDP in accordance with a third embodiment of the present invention. The manufacturing method of the soft mold using a material of liquid silicon rubber is similar to that of the first embodiment.

As illustrated in the drawing, the soft rolling mold 50 is formed by attaching the soft mold 52 to wrap the metal cylinder 51.

In the present invention described above, the soft rolling mold for forming barrier ribs of a PDP is manufactured using elastic silicon rubber. When a mold is fabricated in this method, various cell structures, i.e., barrier rib structure, can be embodied easily by changing the design of a photomask.

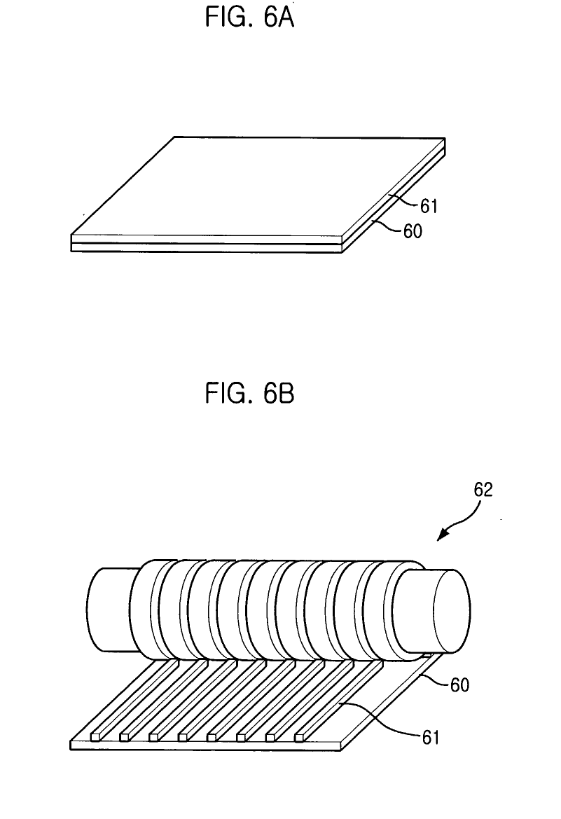

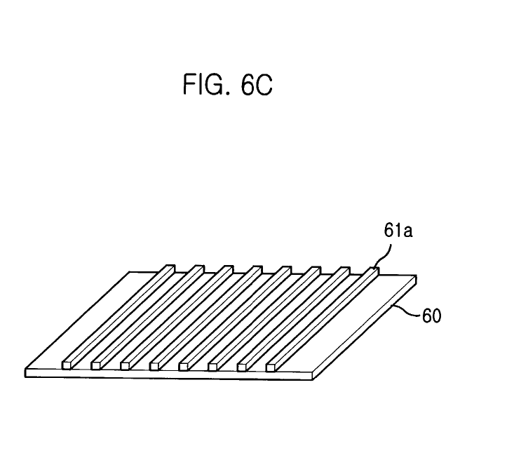

FIGS. 6A through 6C represents a method for forming barrier ribs of a PDP using the soft rolling mold in accordance with the third embodiment of the present invention. First, as shown in FIG. 6A, the barrier rib paste 61 is coated on the rear glass substrate 60 to a thickness of 200˜300 μm.

Referring to FIG. 6B, the barrier rib pattern is formed by using the soft rolling mold 62, and the soft rolling mold 62 is rolled by applying an appropriate pressure thereto, while maintaining the temperature of the substrate at 30˜80° C.

Referring to FIG. 6C, the barrier ribs are formed using the soft rolling mold 62, and then plasticity process is performed at 500˜580° C. to burn out the organic substances in the barrier rib paste 61. With inorganic materials left, barrier ribs 61a of 110˜130 μm height are obtained.

This method has advantages that the process is simple as the conventional method of using metal rolling mold, and the substrate is protected from damages. In addition, when the soft rolling method is used, uniform barrier rib pattern can be obtained, because a rolling mold made of elastic material is used instead of metal.

From the actual experiment, it is observed that when the barrier ribs are formed using a conventional metal rolling mold, some barrier ribs are deteriorated due to the fractional force, and the height of the barrier ribs has a deviation of about 5% from the average height. On the other hand, when the barrier ribs are formed in accordance with the present invention, the height of the barrier ribs shows a deviation of 0.5% from the average height. In the conventional method using a metal rolling mold, it is hard to form uniform barrier ribs in the successive process, because the barrier rib paste adheres to the rolling mold between the cells of the barrier ribs. However, in the method of the present invention, since the silicon or urethane rubber has smaller surface tension and fractional force compared to metal, the paste hardly adheres to the mold in the rolling process, thus forming uniform barrier ribs in the successive rolling process.

As described above, the present invention makes it possible to form barrier ribs with uniform height, thus securing a method of manufacturing good resolution PDP. Also, various barrier rib patterns can be embodied easily by altering the design of basic mold using a photoresist. When the transparent mold is made of a material with elasticity, such as transparent silicon rubber, the substrate can be protected from camber or damage, which will be led to increasing PDP throughput. In addition, the damage on the barrier rib pattern caused in the mold-separation process can be minimized, because the mold is separated easily.

While the present invention has been described with respect to certain preferred embodiments, it will be apparent to those skilled in the art that various changes and modifications may be made without departing from the scope of the invention as defined in the following claims.

What is claimed is:

1. A method for manufacturing a transparent soft mold for forming barrier ribs of a plasma display panel, comprising the steps of:
coating a photoresist on a substrate, the surface of the substrate coated with an adhesive;
forming a basic mold frame which is made of the photoresist and defines a barrier rib pattern;
pouring a liquid-phase transparent rubber material to the basic mold frame;
hardening the liquid-phase transparent rubber material; and
obtaining a transparent soft mold by separating the hardened rubber material from the basic mold frame.

2. The method as recited in claim 1, wherein the substrate is a glass plate.

3. The method as recited in claim 1, wherein the adhesive is a coupling agent of silicon family.

4. The method as recited in claim 1, wherein the photoresist is a negative photoresist that can perform patterning on a thick layer with a dried thickness of 300 μm.

5. The method as recited in claim 1, wherein the rubber material is one selected from the group consisting of urethane rubber and liquid-phase transparent silicon rubber.

6. The method as recited in claim 1, wherein the rubber material is liquid-phase transparent silicon rubber which is hardened in the room temperature and whose optical transmittance is more than 80%.

7. A method for forming barrier ribs of a plasma display panel, comprising the steps of:
preparing a mold which is made of a transparent rubber material and engraved with a barrier rib pattern;
forming a material layer for barrier ribs on a substrate;
aligning the mold on the material layer for barrier ribs;
pressing the material layer for barrier ribs with the mold;
inducing a photopolymerization reaction in the material layer for barrier ribs by exposing the material layer for barrier ribs to light;
separating the mold from the material layer for barrier ribs; and
forming barrier ribs by performing plasticity process on the material layer for barrier ribs.

8. The method as recited in claim 7, wherein the mold is made of liquid-phase transparent silicon rubber which is hardened in the room temperature and whose optical transmittance is more than 80%.

9. The method as recited in claim 7, wherein the material layer for barrier ribs is formed of a photopolymerizing photosensitive barrier rib paste.

10. The method as recited in claim 7, wherein the material layer for barrier ribs is formed of a photopolymerizing photosensitive barrier rib paste including 5˜10 wt % binder polymer, 10˜13 wt % multifunctional monomer or oligomer, 70˜72 wt % inorganic barrier rib powder, 1˜2 wt % photoinitiator, 0.5˜1.0 wt % release agent, at least one additional agent selected from the group of dispersing agent, photo-sensitizer, antifoaming agent, leveling agent, antioxidant and polymerization inhibitor, and 1˜2 wt % solvent.

11. The method as recited in claim 7, wherein the mold for forming barrier ribs is separated as if it were rolled up after exposed to UV light.
